(19) United States
(12) Patent Application Publication
(10) Pub. No.: US 2026/0343757 A1
(43) Pub. Date: Oct. 29, 2026

(54) ELECTRONIC DEVICE

(71) Applicant: Merry Electronics(Shenzhen) Co., Ltd., ShenZhen (CN)

(72) Inventor: Wei-Sheng Shih, Taichung (TW)

(73) Assignee: Merry Electronics(Shenzhen) Co., Ltd., ShenZhen (CN)

(21) Appl. No.: 19/215,357

(22) Filed: May 22, 2025

(30) Foreign Application Priority Data
Apr. 25, 2025 (TW) 114115637

(51) Int. Cl. H05K 5/02; H05K 5/00; H05K 5/15

(52) U.S. Cl. CPC H05K 5/0217; H05K 5/0086; H05K 5/15

(57) ABSTRACT

An electronic device including a housing, an electronic element and a movable member is provided. The housing includes an accommodation space. The electronic element is detachably disposed in the accommodation space. The movable member is movably connected to the housing, and the movable member includes a rotating shaft and a cover plate connected to each other. When the movable member is in a closed state to engage with the housing and cover the accommodation space, the movable member first slides relative to the housing along a first direction and then moves relative to the housing along a second direction, so that the cover plate is separated from the housing and the rotating shaft rotates relative to the housing, so that the movable element is in an open state. The first direction is different from the second direction.

### CROSS-REFERENCE TO RELATED APPLICATION

This application claims the priority benefit of Taiwan application serial no. 114115637, filed on Apr. 25, 2025. The entirety of the above-mentioned patent application is hereby incorporated by reference herein and made a part of this specification.

### BACKGROUND

### Technical Field

The disclosure relates to an electronic device.

### Description of Related Art

The modern electronic device includes a housing and a battery. The battery may be fixed inside the housing through the screws, the glue, or the engaging structures, which are not convenient for disassembly and replacement. The housing may include a slidable battery cover, which may slide to expose the battery. The battery cover can easily slide due to the mistouch or the unexpected force, resulting in accidental exposure, damage, or detachment of the battery.

The disclosure provides an electronic device that is convenient to use.

The electronic device of the disclosure includes a housing, an electronic element, and a movable member. The housing includes an accommodation space. The electronic element is detachably disposed in the accommodation space. The movable member is movably connected to the housing, and the movable member includes a rotating shaft and a cover plate connected to each other. When the movable member is in a closed state to engage with the housing and cover the accommodation space, the movable member first slides along a first direction relative to the housing and then moves along a second direction relative to the housing, so that the cover plate disengages from the housing and the rotating shaft rotates relative to the housing, thereby the movable member is in an open state. The first direction is different from the second direction.

Based on the above, the movable member of the electronic device of the disclosure may move along the different first direction and second direction to switch from the closed state to the open state, to avoid the movable member opening relative to the housing due to the mistouch or the unexpected force and exposing the electronic element. In the closed state, the movable member covers the accommodation space to protect the electronic element. In the open state, the cover plate of the movable member disengages from the housing to expose the electronic element, facilitating disassembly or replacement of the electronic element. Thereby, the reliability and convenience of the electronic device is improved.

### BRIEF DESCRIPTION OF THE DRAWINGS

FIG. 1 is a schematic diagram of an electronic device according to an embodiment of the disclosure.

FIG. 2 is an enlarged view of a partial area A1 of the electronic device in FIG. 1.

FIG. 3 is an exploded view of the electronic device.

FIG. 4 is a schematic diagram of the housing in FIG. 3 from another viewing angle.

FIG. 5 is an enlarged view of a partial area A2 of the housing in FIG. 4.

FIG. 6A is a schematic diagram of the movable member in FIG. 1 after being subjected to force.

FIG. 6B is an enlarged view of a partial area A3 of the electronic device in FIG. 6A.

FIG. 7 and FIG. 8 are schematic diagrams of the movable member in FIG. 6A after being subjected to force.

### DESCRIPTION OF THE EMBODIMENTS

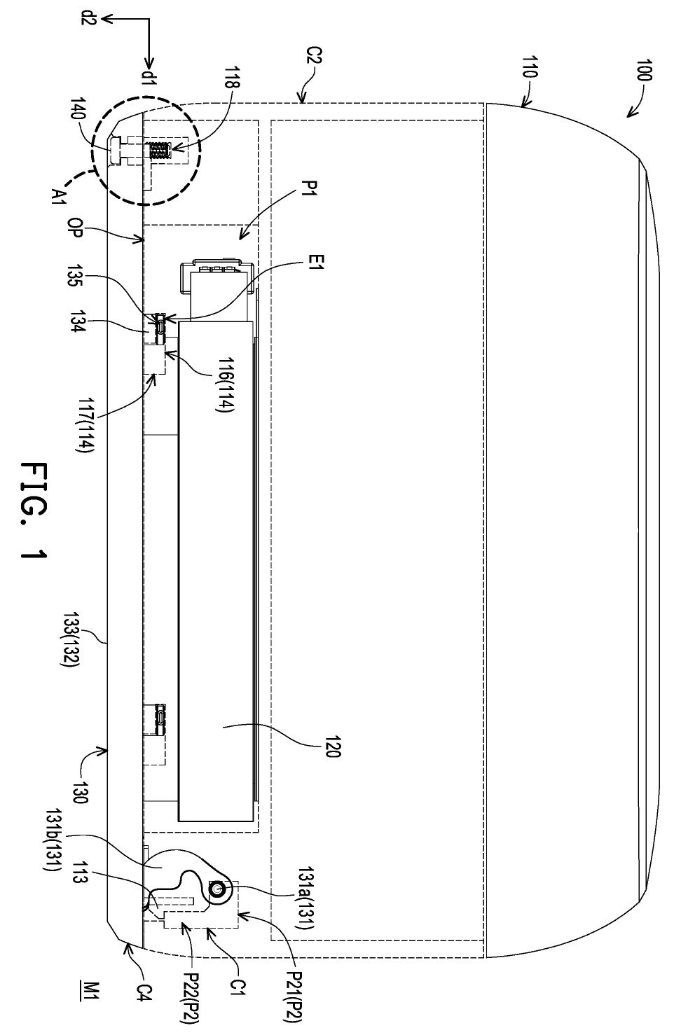

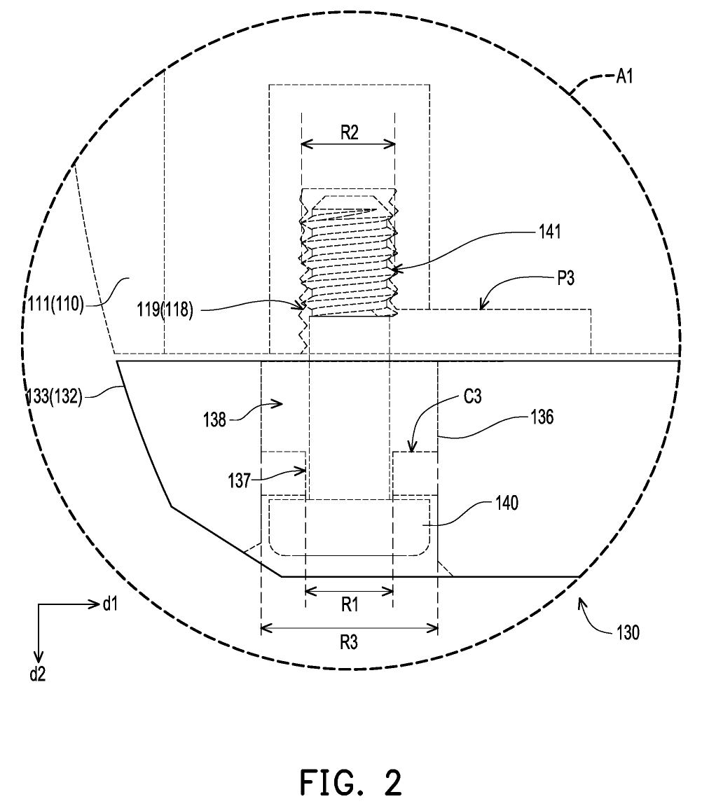

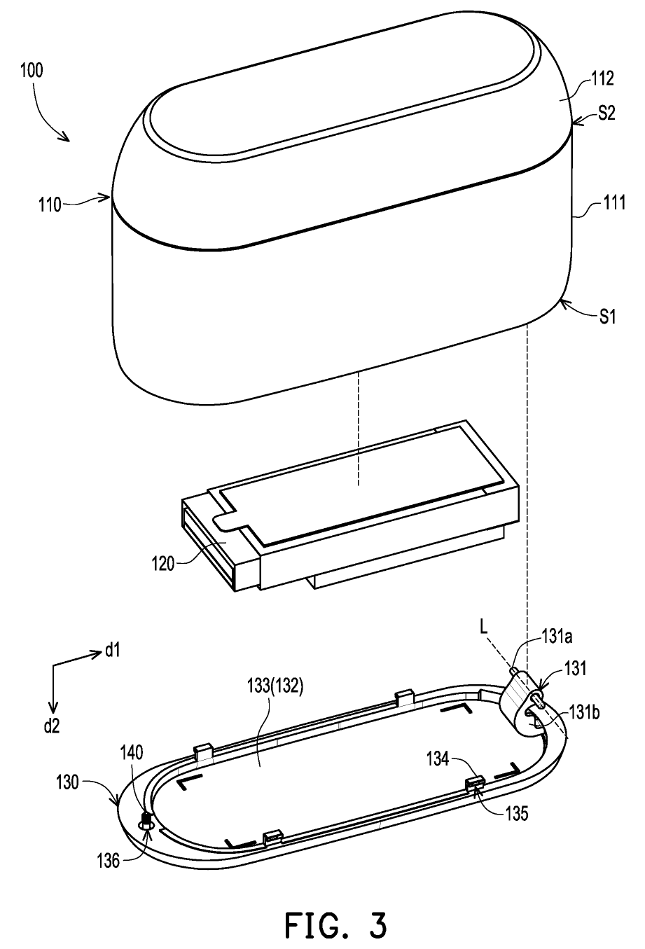

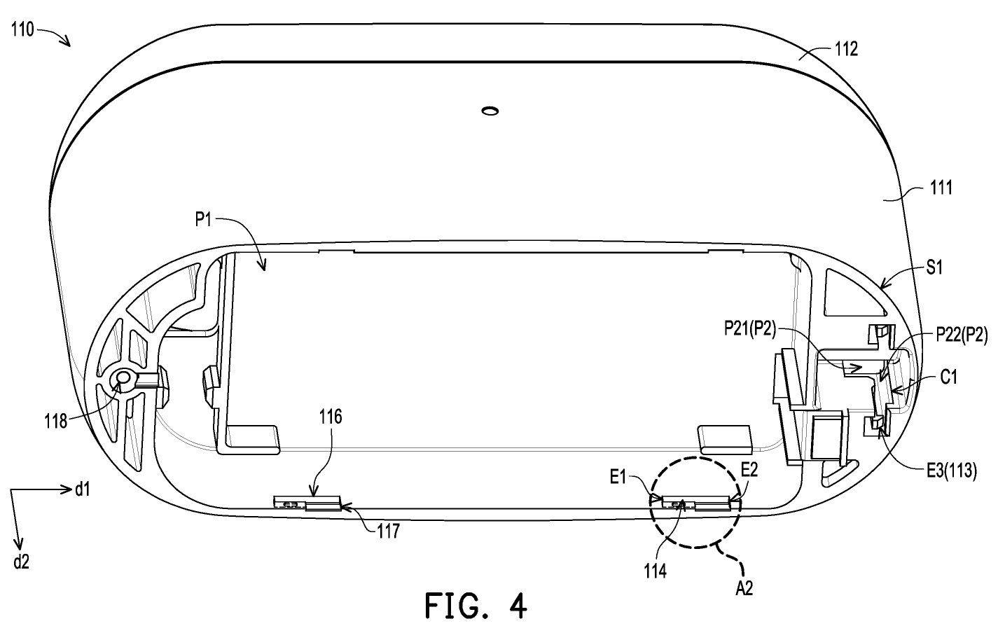

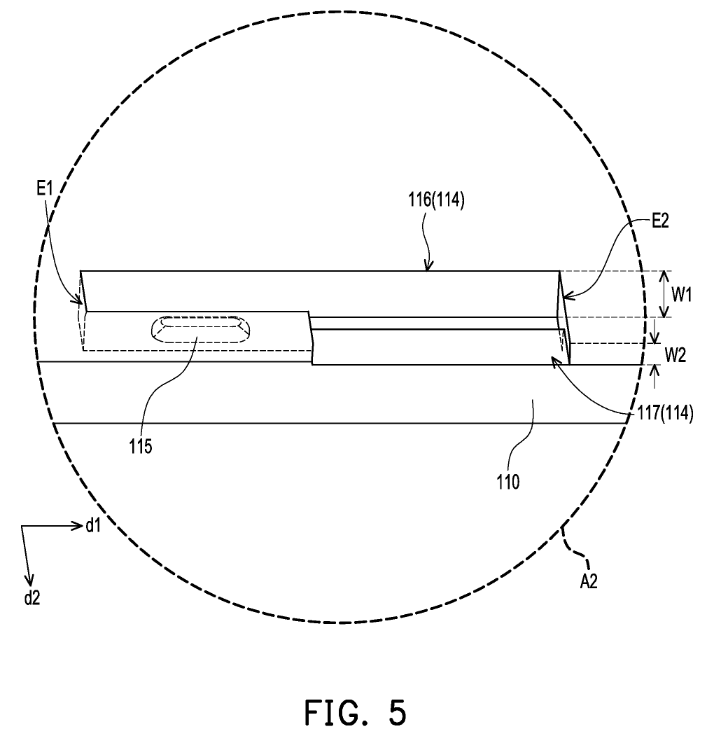

FIG. 1 is a schematic diagram of an electronic device according to an embodiment of the disclosure. FIG. 2 is an enlarged view of a partial area A1 of the electronic device in FIG. 1. FIG. 3 is an exploded view of the electronic device. FIG. 4 is a schematic diagram of the housing in FIG. 3 from another viewing angle. FIG. 5 is an enlarged view of a partial area A2 of the housing in FIG. 4. Refer to FIG. 1 to FIG. 5 at the same time, the electronic device 100 includes a housing 110, an electronic element 120, and a movable member 130. The housing 110 includes an accommodation space P1. The electronic element 120 is detachably disposed in the accommodation space P1. The movable member 130 is movably connected to the housing 110, and includes a rotating shaft 131 and a cover plate 132 connected to each other. In this embodiment, the electronic device 100 is, for example, a charging case of a wireless earphones (not shown), and the electronic element 120 is, for example, a battery, but not limited thereto.

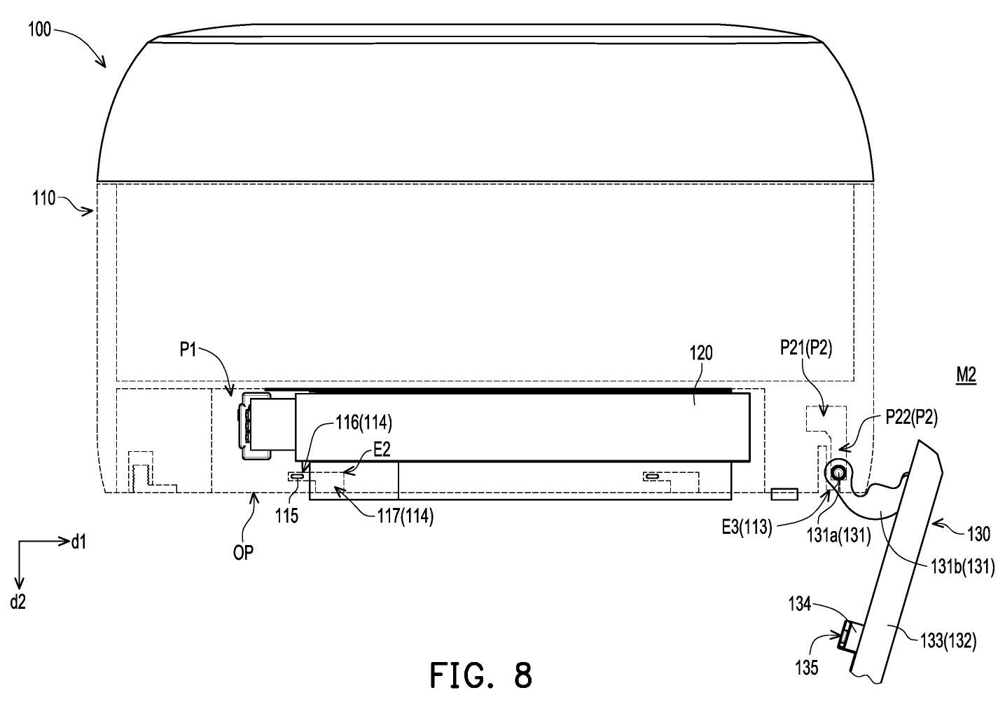

When the movable member 130 is in a closed state M1 to engage with the housing 110 and cover the accommodation space P1, the movable member 130 may initially slide relative to the housing 110 along a first direction d1 by a force and then move relative to the housing 110 along a second direction d2 by another force, causing the cover plate 132 to disengage from the housing 110 and the rotating shaft 131 to rotate relative to the housing 110, thereby the movable member 130 is in an open state M2 (shown in FIG. 8). The first direction d1 is different from the second direction d2, and the first direction d1 may be vertical to the second direction d2. The second direction d2 is a gravity direction, but not limited thereto. When the movable member 130 is in the open state M2, the electronic element 120 disposed in the accommodation space P1 is exposed for convenient disassembly or replacement, thereby enhancing the convenience of using the electronic device 100.

The movable member 130 of the electronic device 100 of this embodiment moves relative to the housing 110 through two different movement directions, thereby switching between the closed state M1 and the open state M2. Thereby, it may avoid the movable member 130 being directly opened relative to the housing 110 due to mistouch or unexpected external force, thus enhancing the reliability of the electronic device 100. The structure of the electronic device 100 of this embodiment is simple and convenient to use.

As shown in FIGS. 3-5 , the housing 110 includes a first housing 111 and a second housing 112. The movable member 130 is movably connected to a side S1 of the first housing 111, and the second housing 112 is pivotally connected to another side S2 of the first housing 111. The wireless earphones may enter the first housing 111 from the side S2 of the first housing 111, and the accommodation space P1 is located at the side S1. An opening OP of the accommodation space P1 is located at the side S1. The housing 110 further includes a connecting channel P2, a connecting member 113, and an inner wall surface C1. The connecting member 113 is located at the first housing 111 and forms the connecting channel P2 together with the inner wall surface C1. The connecting channel P2 includes a first channel P21 and a second channel P22 connected to each other. The first channel P21 extends along the first direction d1, the second channel P22 extends along the second direction d2, and the connecting channel P2 is L-shaped. The rotating shaft 131 of the movable member 130 is movably connected to the connecting channel P2. When the movable member 130 is acted upon by the force, the rotating shaft 131 moves within the connecting channel P2.

An end E3 of the connecting member 113 is hook-shaped, and the rotating shaft 131 may enter the connecting channel P2 from the hook-shaped end E3 of the connecting member 113. The rotating shaft 131 may push the connecting member 113 to deform and move into the connecting channel P2. When the rotating shaft 131 moves along the second direction d2, the end E3 of the connecting member 113 may stop the rotating shaft 131 to prevent the rotating shaft 131 (the movable member 130) from completely disengaging from the housing 110.

The housing 110 further includes a connecting slot 114 and a protrusion 115. The connecting slot 114 is formed in the first housing 111 and is located in the accommodation space P1. The connecting slot 114 includes a first slot 116 and a second slot 117. The first slot 116 extends along the first direction d1 and includes a first end E1 and a second end E2 opposite to each other. The second slot 117 extends along the second direction d2 and is connected to the second end E2. The connecting slot 114 is L-shaped. The protrusion 115 is connected to the first housing 111 and is located at the first end E1 of the first slot 116. A depth W1 of the first slot 116 in a direction perpendicular to the first direction d1 and the second direction d2 is greater than a depth W2 of the second slot 117 in a direction perpendicular to the first direction d1 and the second direction d2.

As shown in FIG. 5, the rotating shaft 131 of the movable member 130 includes a shaft 131a and a connecting portion 131b. The cover plate 132 includes a cover body 133 and an engaging member 134 connected to each other, and includes a recess 135. The shaft 131a of the rotating shaft 131 is passed through the connecting portion 131b and is movably connected to the connecting channel P2 of the housing 110. The connecting portion 131b is connected to the cover body 133 of the cover plate 132. A rotation axis L of the shaft 131a is perpendicular to the first direction d1 and the second direction d2. The movable member 130 may rotate relative to the housing 110 through the shaft 131a. The cover body 133 may cover the opening OP of the housing 110. The engaging member 134 is hook-shaped, and the hook-shaped portion of the engaging member 134 may extend into the connecting slot 114 to engage with the housing 110. The recess 135 is located on the engaging member 134. The hook-shaped portion of the engaging member 134 may move within the connecting slot 114, allowing the recess 135 to engage with or disengage from the protrusion 115 of the housing 110, thereby providing a tactile feel of jamming. The number of the engaging members 134 of the embodiment is four, the four engaging members 134 are connected in corresponding pairs to both sides of the cover body 133, but not limited thereto.

As shown in FIG. 2, the electronic device 100 optionally further includes a fastener 140. The cover plate 132 of the movable member 130 correspondingly includes a first connecting hole 136, and the housing 110 correspondingly includes a second connecting hole 118 and an accommodation channel P3. The first connecting hole 136 is located on the cover body 133, and is positioned at the opposite end of the cover body 133 from the connecting portion 131b of the rotating shaft 131 in the first direction d1. The fastener 140 is passed through the first connecting hole 136. A portion of the fastener 140 has an external thread 141, and a portion of the fastener 140 may be a smooth cylinder. The first connecting hole 136 includes a first portion 137 and a second portion 138 connected to each other. A diameter R1 of the first portion 137 is slightly smaller than an outer diameter R2 of the external thread 141, and a diameter R3 of the second portion 138 is greater than the outer diameter R2 of the external thread 141. The accommodation channel P3 connects to the second connecting hole 118 and extends along the first direction d1. The second connecting hole 118 has an internal thread 119, and the external thread 141 of the fastener 140 may engage with the internal thread 119. The portion of the fastener 140 having the external thread 141 may be squeezed into the second slot 117. When the fastener 140 is disconnected from the second connecting hole 118, the external thread 141 may abut against a bottom surface C3 of the second portion 138, to prevent the fastener 140 from completely disengaging from the cover plate 132 of the movable member 130.

As shown in FIGS. 1 and 2 , when the movable member 130 is in the closed state M1, the engaging member 134 of the movable member 130 is slidably engaged with the connecting slot 114 of the housing 110, and the hook-shaped portion of the engaging member 134 is positioned at the first end E1 of the connecting slot 114. The movable member 130 is stably connected to the housing 110, and the protrusion 115 of the housing 110 is positioned within the recess 135 and engaged with the recess 135. The shaft 131a of the rotating shaft 131 is positioned at one end of the first channel P21 of the connecting channel P2 away from the second channel P22. The shaft 131a and connecting portion 131b of the rotating shaft 131 are located inside the housing 110. The cover body 133 of the cover plate 132 covers the opening OP of the housing 110, to prevent the electronic element 120 in the accommodation space P1 from being exposed. In the closed state M1, the first connecting hole 136 of the movable member 130 aligns with the second connecting hole 118. At this time, the portion of the fastener 140 having the external thread 141 may be engaged with the internal thread 119 of the second connecting hole 118, making the movable member 130 more stably connected to the housing 110. The outer surface C4 of the movable member 130 forms a smooth curve with the outer surface C2 of the housing 110, to maintain the aesthetic appearance of the electronic device 100.

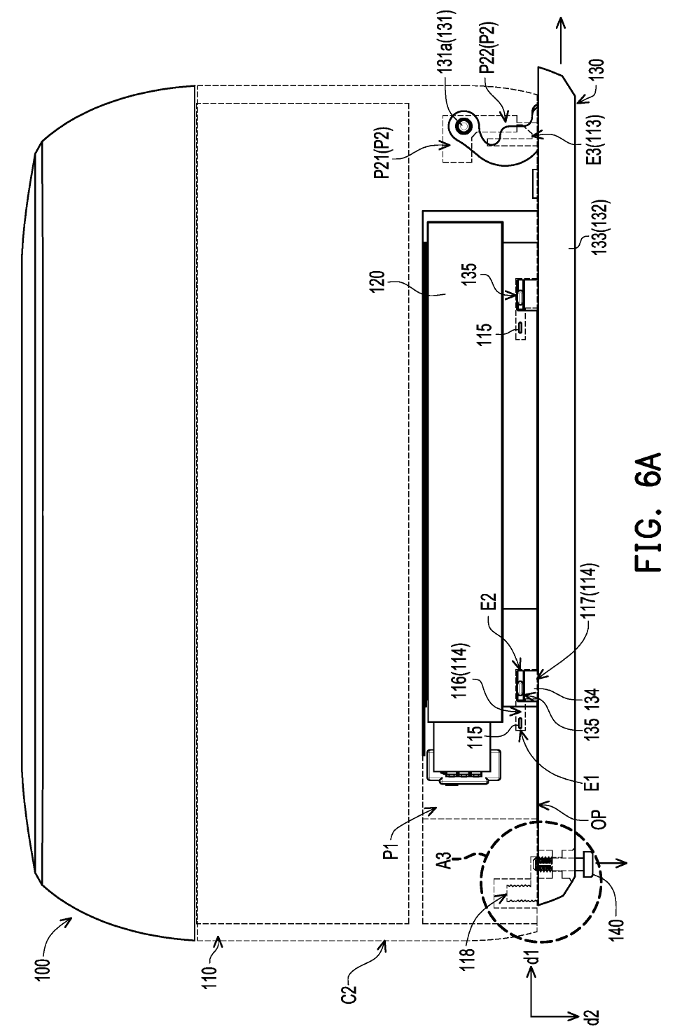

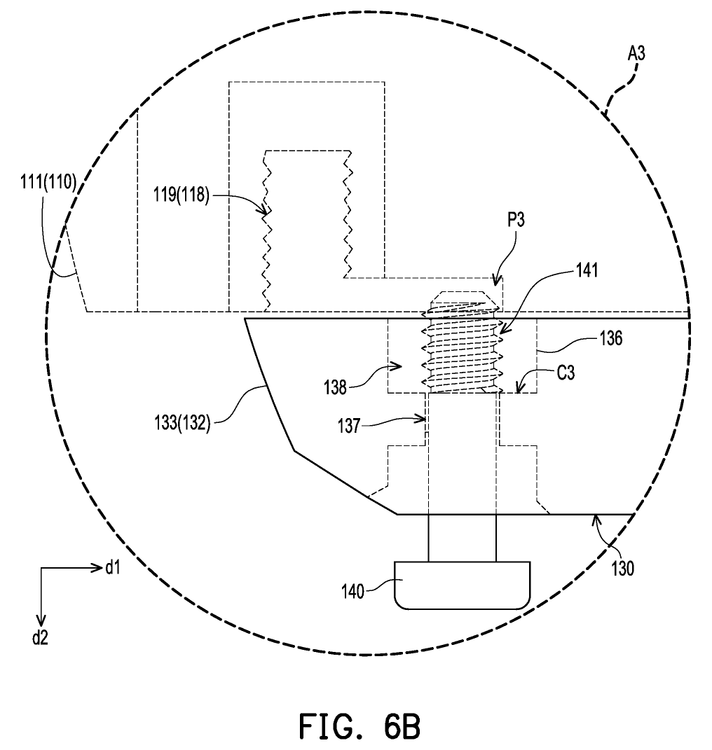

FIG. 6A is a schematic diagram of the movable member in FIG. 1 after being subjected to force. FIG. 6B is an enlarged view of a partial area A3 of the electronic device in FIG. 6A. Refer to FIG. 1, FIGS. 6A and 6B at the same time. Before the movable member 130 is subjected to force along the first direction d1 and moves from the position in FIG. 1 to the position in FIG. 6A, the fastener 140 is first subjected to force to disengage the external thread 141 from the internal thread 119. The external thread 141 abuts against the bottom surface C3 of the second portion 138 of the first connecting hole 136, but not limited thereto. In an embodiment not shown, the fastener 140 may completely withdraw from the second connecting hole 118 of the housing 110 after being subjected to force.

Subsequently, the movable member 130 may slide relative to the housing 110 along the first direction d1 by the force. During the sliding process of the movable member 130, the recess 135 moves away from the protrusion 115 of the housing 110, generating the tactile feel of jamming. The hook-shaped portion of the engaging member 134 slides within the first slot 116 of the connecting slot 114, sliding from the first end E1 to the second end E2. The rotating shaft 131 slides within the first channel P21 of the connecting channel P2 approaching the second channel P22. A portion of the cover body 133 (the cover plate 132) of the movable member 130 protrudes from the outer surface C2 of the housing 110 in the first direction d1, facilitating subsequent operation. A portion of the fastener 140 moves from the second connecting hole 118 of the housing 110 into the accommodation channel P3. At this time, the cover body 133 still covers the opening OP of the housing 110, and the electronic element 120 in the accommodation space P1 still cannot leave the accommodation space P1.

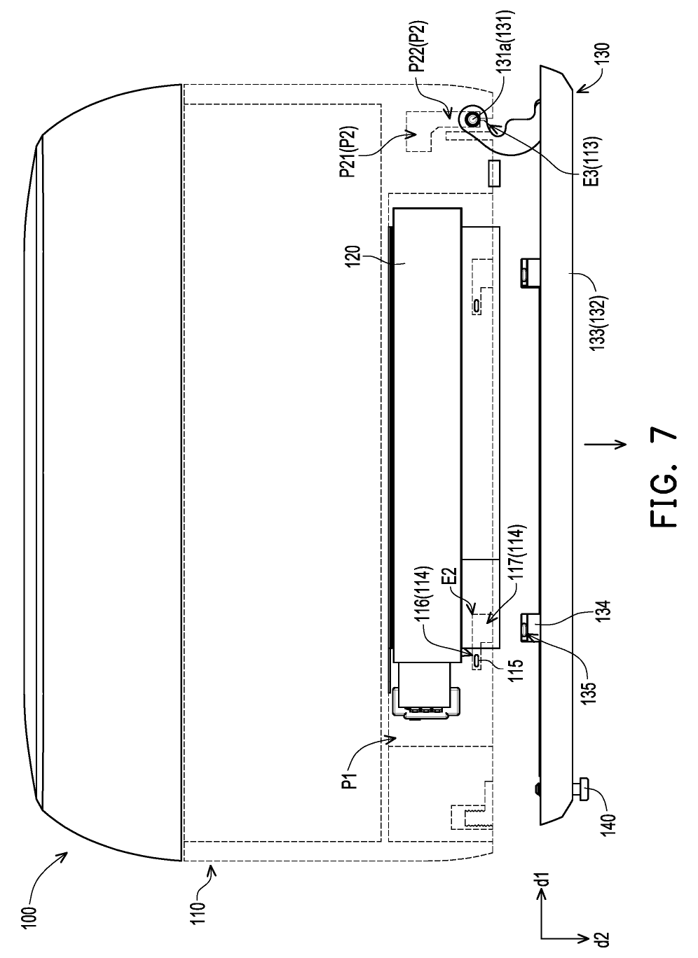

FIGS. 7 and 8 are schematic diagrams of the movable member in FIG. 6A after being subjected to force. Refer to FIGS. 6A, 7 and 8, at the same time. The movable member 130 may subsequently move relative to the housing 110 by another force along the second direction d2. The portion of the cover plate 132 protruding from the outer surface C2 of the housing 110 may be subjected to force, causing the movable member 130 to first move from the position in FIG. 6A along the second direction d2 to the position in FIG. 7. Since the depth W2 of the second slot 117 of the connecting slot 114 is less than the depth W1 of the first slot 116 (shown in FIG. 5), when the movable member 130 moves under force, the user only needs to apply the smaller force to make the engaging member 134 withdraw from the connecting slot 114. At this time, the engaging member 134 slides along the second slot 117 of the connecting slot 114, and disengages from the connecting slot 114 at an end of the second slot 117 away from the first slot 116. The rotating shaft 131 moves within the second channel P22 of the connecting channel P2 away from the first channel P21. The hook-shaped end E3 of the connecting member 113 stops the movement of the rotating shaft 131 in the second direction d2.

Since the second direction d2 is the gravity direction, after the engaging member 134 (the cover plate 132) of the movable member 130 disengages from the housing 110, the rotating shaft 131 (the shaft 131a) of the movable member 130 rotates relative to the housing 110 around the rotation axis L (shown in FIG. 3) under the effect of the gravity. The movable member 130 automatically rotates from the position in FIG. 7 to the position in FIG. 8, switching to the open state M2. In the open state M2, the engaging member 134 of the movable member 130 withdraws from the connecting slot 114 of the housing 110. A portion of the connecting portion 131b of the rotating shaft 131 is located outside the housing 110, and the shaft 131a of the rotating shaft 131 is located inside the housing 110 and abuts against the hook-shaped end E3 of the connecting member 113. The cover body 133 of the cover plate 132 is away from the opening OP of the accommodation space P1, exposing the electronic element 120. The user may easily remove or replace the electronic element 120. In an embodiment not shown, the second direction d2 may be opposite to the gravity direction, and after the engaging member 134 disengages from the housing 110, the user may manually rotate the cover plate 132 to switch the movable member 130 to the open state M2.

When the movable member 130 needs to be switched from the open state M2 to the closed state M1 (shown in FIG. 1), the movable member 130 first rotates from the position in FIG. 8 to the position in FIG. 7 with the shaft 131a of the rotating shaft 131 as the axis by the force. Then, the movable member 130 may move from the position in FIG. 7 to the position in FIG. 6A. During the movement of the movable member 130 by a force opposite to the second direction d2, the rotating shaft 131 moves from the second channel P22 toward the first channel P21, the engaging member 134 of the movable member 130 enters the second slot 117 of the connecting slot 114, and moves toward the second end E2 of the first slot 116 to engage with the connecting slot 114. Subsequently, the movable member 130 may move from the position in FIG. 6A to the position in FIG. 1 by a force opposite to the first direction d1. During the movement of the movable member 130, the rotating shaft 131 moves away from the second channel P22, and the engaging member 134 moves toward the first end E1 of the first slot 116. The recess 135 on the engaging member 134 engages with the protrusion 115 inside the connecting slot 114, generating the tactile feel of jamming and making the movable member 130 stably connected to the housing 110. At this point, the movable member 130 switches to the closed state M1. At this time, the external thread 141 of the fastener 140 may engage with the internal thread 119 of the housing 110 to make the movable member 130 more stably connected to the housing 110. Thereby, the movable member 130 of the electronic device 100 may move relative to the housing 110 through two different movement paths, switching between the closed state M1 and the open state M2.

In summary, the movable member of the electronic device of the disclosure may move along the different first direction and second direction to switch from the closed state to the open state, to avoid the movable member opening relative to the housing due to the mistouch or the unexpected force and exposing the electronic element. In the closed state, the movable member covers the accommodation space to protect the electronic element. In the open state, the cover plate of the movable member disengages from the housing to expose the electronic element, facilitating disassembly or replacement of the electronic element. Thereby, the reliability and convenience of the electronic device is improved.

What is claimed is:

1. An electronic device, comprising:
a housing, comprising an accommodation space;
an electronic element, detachably disposed in the accommodation space; and
a movable member, movably connected to the housing, the movable member comprises a rotating shaft and a cover plate connected to each other,
when the movable member is in a closed state to engage with the housing and cover the accommodation space, the movable member first slides along a first direction relative to the housing and then moves along a second direction relative to the housing, to disengage the cover plate from the housing and to rotate the rotating shaft relative to the housing, thereby the movable member is in an open state, the first direction is different from the second direction.

2. The electronic device as claimed in claim 1, wherein the first direction is vertical to the second direction.

3. The electronic device as claimed in claim 1, wherein the second direction is a gravity direction.

4. The electronic device as claimed in claim 1, wherein the cover plate comprises a cover body and an engaging member connected to each other, the housing comprises a connecting slot, when the movable member is in the closed state, the engaging member is positioned at a first end of the connecting slot, when the movable member slides along the first direction, the engaging member is positioned at a second end of the connecting slot.

5. The electronic device as claimed in claim 4, wherein the connecting slot comprises a first slot and a second slot, the first slot extends along the first direction and comprises the first end and the second end, the second slot extends along the second direction and is connected to the second end.

6. The electronic device as claimed in claim 5, wherein a depth of the first slot is greater than a depth of the second slot.

7. The electronic device as claimed in claim 1, wherein the cover plate further comprises a recess, the housing comprises a protrusion, when the movable member is in the closed state, the protrusion is positioned inside the recess.

8. The electronic device as claimed in claim 1, wherein the rotating shaft comprises a shaft and a connecting portion, the shaft is passed through the connecting portion, the connecting portion is connected to the cover plate, a rotation axis of the shaft is vertical to the first direction and the second direction, the shaft is movably connected to the housing.

9. The electronic device as claimed in claim 8, when the movable member is in the closed state, the rotating shaft is positioned inside the housing, when the movable member is in the open state, a portion of the connecting portion is positioned outside the housing and the shaft is positioned inside the housing.

10. The electronic device as claimed in claim 1, wherein the housing comprises a connecting channel, the rotating shaft is movably connected to the connecting channel, the connecting channel comprises a first channel and a second channel connected to each other, the first channel extends along the first direction, the second channel extends along the second direction.

11. The electronic device as claimed in claim 10, wherein the housing comprises a connecting member and an inner wall surface, the connecting member and the inner wall surface together form the connecting channel, when the movable member is in the open state, the rotating shaft abuts against an end of the connecting member.

12. The electronic device as claimed in claim 1, further comprising a fastener, wherein the cover plate comprises a first connecting hole, the housing comprises a second connecting hole, the fastener is passed through the first connecting hole, when the movable member is in the closed state, the fastener is connected to the second connecting hole.

13. The electronic device as claimed in claim 12, wherein a portion of the fastener has an external thread, the second connecting hole has an internal thread, when the movable member is in the closed state, the external thread engages with the internal thread, before the movable member slides along the first direction, the external thread and the internal thread disengage.
